(19) United States
(12) Patent Application Publication
(10) Pub. No.: US 2019/0025385 A1
(43) Pub. Date: Jan. 24, 2019

(54) GAS-SENSITIVE HALL DEVICE

(71) Applicant: Infineon Technologies AG, Neubiberg (DE)

(72) Inventors: Werner Breuer, Sinzing-Viehhausen (DE); Markus Eckinger, Regenstauf (DE)

(21) Appl. No.: 16/141,394

(22) Filed: Sep. 25, 2018

Related U.S. Application Data
(63) Continuation-in-part of application No. 15/247,336, filed on Aug. 25, 2016, now Pat. No. 10,082,484.

(30) Foreign Application Priority Data
Sep. 17, 2015 (DE) 102015115667.9

(51) Int. Cl. G01R 33/07; G01N 27/26; G01N 27/74; G01N 27/12; H05B 3/20

(52) U.S. Cl. CPC G01R 33/075; G01N 27/26; H05B 3/20; G01N 27/123; G01N 27/74

(57) ABSTRACT

A chemically sensitive Hall device having a substrate; a chemically sensitive layer arranged on the substrate and configured to operably interact with atoms or molecules of a gaseous or liquid fluid; first electrodes connected to the chemically sensitive layer and configured to feed a sensor current through the chemically sensitive layer along a first direction; and second electrodes connected to the chemically sensitive layer and configured to tap a Hall voltage at the chemically sensitive layer along a second direction.

### TECHNICAL FIELD

The invention relates to the field of gas sensors. In particular to a gas-sensitive Hall device for detecting specific gases using the Hal effect.

### BACKGROUND

Gas sensors can be used to measure the concentration of a target gas. In most gas sensors the target gas is oxidized or reduced an electrode which results in a measureable sensor current. Integrated gas sensors utilize gas sensitive layers disposed on a semiconductor substrate. Many commercial chemical gas sensors utilize gas-sensitive metal oxide (MOX) layers disposed on semiconductor material. Such sensors may be produced at comparably low costs and exhibit a high sensitivity. Among MOX materials tin oxide is frequently used in solid-state sensors.

Recently graphene is used as a gas-sensitive sensor material due to its unique electrical properties. The band structure of graphene makes it particularly sensitive to chemical doping. The withdrawal or donation of even a few electrons shifts the Fermi level significantly away from the Dirac point, and thus even a small change in the number of charge carriers has a significant effect on the resistance of a graphene layer. Apart from its band structure, graphene has many other properties that render it particularly suitable for applications in gas sensors. Single-layer graphene has every atom at the surface, has a high metallic conductivity, even when very few charge carriers are present. Furthermore, it has and few crystal defects, which leads to low Johnson noise. The low noise level in graphene devices means that very small changes in resistivity (i.e. small sensor responses) can be measured, leading to highly sensitive sensors. Graphene is also chemically very stable due to its strong bonds and lack of defects. The electric conductivity of graphene allows for direct measurement of resistance, and the robustness of graphene allows for layers, which only one atom thick, to be processed into gas sensors.

Other gas sensors utilize a layer of two-dimensional electron gas (2DEG), which are sensitive to the presence of specific gases. For example, the two-dimensional electron gas (2DEG) formed at the interface of AlGaN/GaN layers grown on silicon substrates may be used for the detection of nitrogen oxides (NOx). In the presence of humidity, the interaction of nitrogen oxide with an open gate area may reversibly changes the conductivity of the 2DEG.

As outlined above, the measureable effect in solid-state gas sensors is usually a change of the electric conductivity (or resistivity) of gas-sensitive layers. Recent research has shown that gas sensitive layers (or generally chemically sensitive layers) such as graphene layers may also be used to form Hall bars. The measureable transversal voltage (e.g. the Hall voltage) due to the Hall effect shows also significant sensitivity to the presence of specific atoms or molecules of gaseous or liquid fluids. It is thus an object of the present invention to provide a sensor which makes use of the Hall effect in chemically sensitive layers.

### BRIEF DESCRIPTION OF THE DRAWINGS

The invention can be better understood with reference to the following description and drawings. The components in the figures are not necessarily to scale, emphasis instead being placed upon illustrating the principles of the invention. Moreover, in the figures, like reference numerals designate corresponding parts. In the drawings:

FIG. 1 is a cross-sectional view of a first exemplary embodiment of a gas-sensitive Hall element including a back gate to control the charge carrier density in the gas sensitive layer of the Hall element.

FIG. 2 is a top view corresponding to the cross-sectional view of FIG. 1

FIG. 3 is a circuit diagram illustrating the use of the Hall element of FIGS. 1 and 2.

FIG. 4 is a cross-sectional view of a second exemplary embodiment of a gas-sensitive Hall element including a heating coil to regenerate the gas-sensitive layer of the Hall element.

FIG. 5 is a cross-sectional view of a third exemplary embodiment of a gas-sensitive Hall element including a permanent magnet to generate a magnetic field to magnetically bias the Hall element.

FIG. 6 illustrates a top view of a fourth exemplary embodiment of a gas-sensitive Hall element including a micro-heater (polycrystalline silicon resistor used for heating);

FIGS. 7A-7E illustrates top views of different geometries, which may be used to form a Hall element.

FIG. 8 includes two diagrams illustrating the ohmic resistivity and the Hall resistivity with regard to the gate voltage applied to the back gate the gas sensor in accordance with FIG. 1.

FIG. 9 illustrates one exemplary circuit for controlling the gate voltage applied to the back gate of a gas sensor in accordance with FIG. 1.

FIG. 10 is a cross-sectional view of a first exemplary embodiment of a gas-sensitive Hall element, which is formed on a silicon membrane.

FIG. 11 is a top view of an array of a Hall elements which may be used for differential measurements or detection of different gases.

FIG. 12 schematically illustrates another example of an array of Hall elements which may be controlled using multiplexer/demultiplexer circuits to select one or more specific Hall elements of the array.

FIG. 13 illustrates a flow chart illustrating a method of operating the gas sensors described herein.

FIGS. 14A-14C illustrates by means of block and timing diagrams two exemplary regulation schemes for regulating the gate voltage applied to the back-gate of a Hall element.

FIG. 15 is a cross-sectional view of a fifth exemplary embodiment of a gas-sensitive Hall device.

FIG. 16 illustrates a flow chart of a method of operating the gas sensitive Hall device of FIG. 15.

FIGS. 17A-17B illustrate spinning current mode examples of the gas-sensitive Hall device of FIG. 15.

### DETAILED DESCRIPTION

In the exemplary embodiments described below, a graphene layer is used as one possible option for a gas-sensitive layer. However, other materials may be used as an alternative to graphene. The choice of the material may depend on the actual application and particularly on the physical and chemical properties of the gas molecules to be detected.

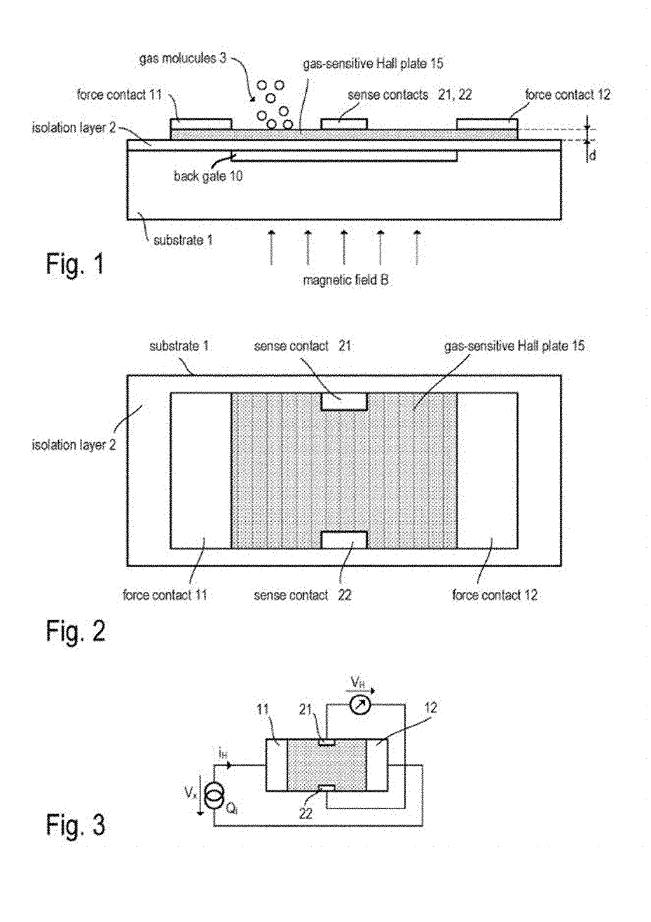

FIG. 1 is a cross-sectional view of an exemplary solid-state gas sensor formed on a silicon substrate 1. FIG. 2 illustrates the corresponding top view. It is noted that other substrate materials may be used as an alternative to silicon. The present illustration shows only the structure of a gas sensor. However, other components and circuits (e.g. control, driver and evaluation circuits) may be integrated in the same substrate and/or in the same chip package as the gas sensor.

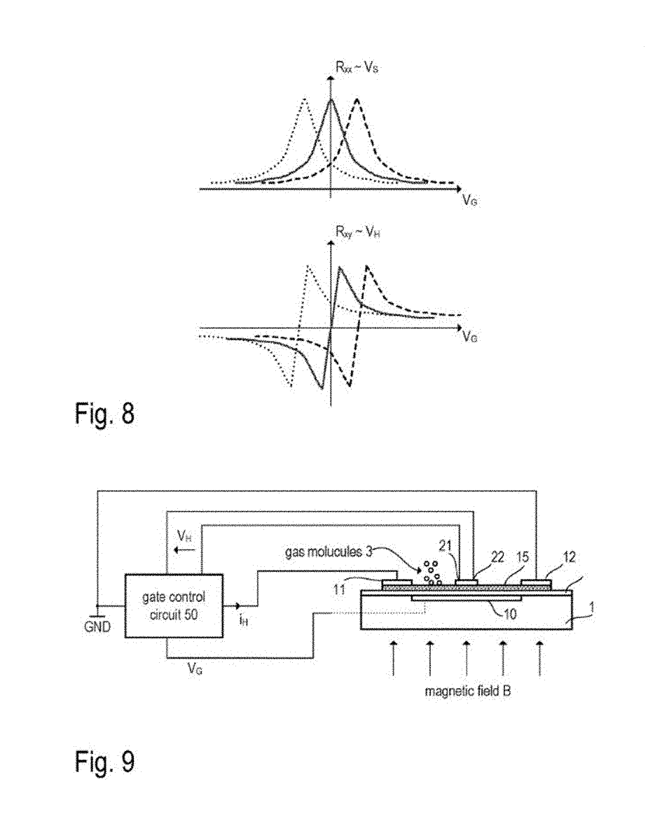

A conductive back-gate region 10 is formed in the substrate 1, for example by deposition of a metal layer (e.g. in a recess on the top surface of the substrate) or by generating a doped semiconductor region, e.g. by diffusion of dopants, ion implantation or the like. Alternatively, a layer of polycrystalline silicon (polysilicon) may be deposited to form the back gate region 10. An isolation layer 2 is formed on the top surface of the substrate 1 so that the isolation layer 2 covers the back-gate region 10 from a gas sensitive layer 15 that is formed on top of the isolation layer 2. In case graphene is used as gas sensitive material for forming the gas-sensitive layer 15, the isolation layer 2 may be made of hexagonal boron nitride (h-BN). Boron nitride is isoelectronic to graphene, and a h-BN underlayment may reduce corrugation of the graphene layer (as compared with using a silicon oxide isolation layer) as well as spatial inhomogeneity of charge carrier density in the graphene layer 15. As mentioned above, the Hall effect, which occurs in the gas-sensitive layer 15 when exposed to a magnetic field B, is to be evaluated in order to detect gas molecules or measure gas concentration. Therefore, the gas-sensitive layer 15 can be regarded as Hall plate (sometimes also referred to as Hall bar). Alternatively, the isolation layer 2 may be formed using Molybdenum disulfide (MoS2) or an oxide or a nitride of other materials (e.g. silicon oxide). As mentioned above, layers forming a two-dimensional electron gases (2DEG) may be used instead of graphene to form the gas-sensitive layer 15. 2DEG layers may occur in III-V semiconductor heterostructures based on, e.g., InAs, InSb, GaAs, GaN, etc. The purpose and the function of the back gate is describes later with reference to FIGS. 8 and 9.

The gas-sensitive Hall plate 15 is contacted by the force contact electrodes 11 and 12, as well as by the sense contact electrodes 21 and 22 (see also top view of FIG. 2), which contact the top surface of the Hall plate 15. The force contact electrodes 11, 12 may be formed by a metal (e.g. gold, aluminum, etc.) and are arranged at opposing ends of the gas-sensitive Hall plate 15 along a longitudinal direction. The sense contact electrodes 21, 22 may also be formed by a metal (e.g. gold, aluminum, etc.) but are arranged at opposing ends of the gas-sensitive Hall plate 15 along a transverse direction (which is perpendicular to the longitudinal direction). The force contact electrodes 11, 12 are used to feed a sensor current i_{H} through the gas-sensitive Hall plate 15 so that the sensor current i_{H} passes through the Hall plate 15 substantially along the longitudinal direction. Due to the Hall effect a voltage arises transversely across the current-carrying Hall plate 15 when being exposed to the magnetic field B, which is oriented perpendicularly to the top surface of the Hall plate 15. This voltage is also referred to as “Hall voltage” and can be tapped at the Hall plate 15 via the sense contact electrodes 21, 22.

FIG. 3 illustrates the above-explained situation with the help of a circuit diagram. Accordingly, a current source Qᵢ generates the sensor current i_{H} that is applied to the first force contact electrode 11, and drained from the second force contact electrode 12. When exposed to a magnetic field as illustrated in FIG. 1, the Hall voltage V_{H} arises between the sense contacts 21 and 22. In FIG. 3 a meter is connected to the sense contacts 21 and 22. It is, however, understood, that this meter is merely representative for any circuit that is used to process the Hall voltage VH in order to determine the desired output indicative of gas molecules 3 interacting with the gas-sensitive Hall plate 15 (see FIG. 1).

The Hall voltage VH can be calculated in accordance with the following equation

V_{H}=R_{H}·i_{H}B/d (1)

wherein d is the thickness of the gas-sensitive Hall plate (see FIG. 1). The proportionality factor R_{H} is generally referred to as Hall constant and has the dimension cubic meter per Coulomb. It can be calculated as:

RH=(n·q)⁻¹ (2)

In equation 2, the parameter n denotes the charge carrier density (e.g. electrons per cubic meter) and the parameter q denotes the charge per charge carrier (e.g. the elementary charge −1,602·10⁻¹⁹ C in case of electrons). In case of electron conduction (q=−e) the Hall constant can also be expressed as:

R_{H}=ρ·μ=μ/σ (3)

wherein ρ denotes the specific resistance of the Hall plate 15 (σ the respective conductivity), and μ denotes the electron mobility. In view of equations 2 and 3 the Hall constant basically depends on the conductivity (which is proportional to the charge carrier density) as well as on the charge carrier mobility.

Gas molecules 3 (see FIG. 1) may be detected as the molecules are adsorbed at the surface of the gas-sensitive layer 15. Due to this interaction between the gas-sensitive layer 15 and the gas molecules 3, the charge-carrier density or the charge carrier mobility (or both) of the layer 15 changes, which results in a respective change of the Hall constant R_{H} and also the specific resistance p of the gas-sensitive layer 15. In gas-sensitive resistive sensors the mentioned change of the specific resistance is measured using Ohm's law thereby producing a comparably small sensor signal. In contrast thereto, the effect is significantly larger when evaluating the Hall voltage. The lower the charge carrier density and the higher the charge carrier mobility, the higher is the Hall constant. The Hall effect can further be “amplified” by the factor B/d (see FIG. 1), when the gas sensitive layer 15 (Hall plate) is thin (d is small) and the magnetic flux density B is high. Thus, highly sensitive gas sensors can be constructed by using thin gas-sensitive layers has Hall plates.

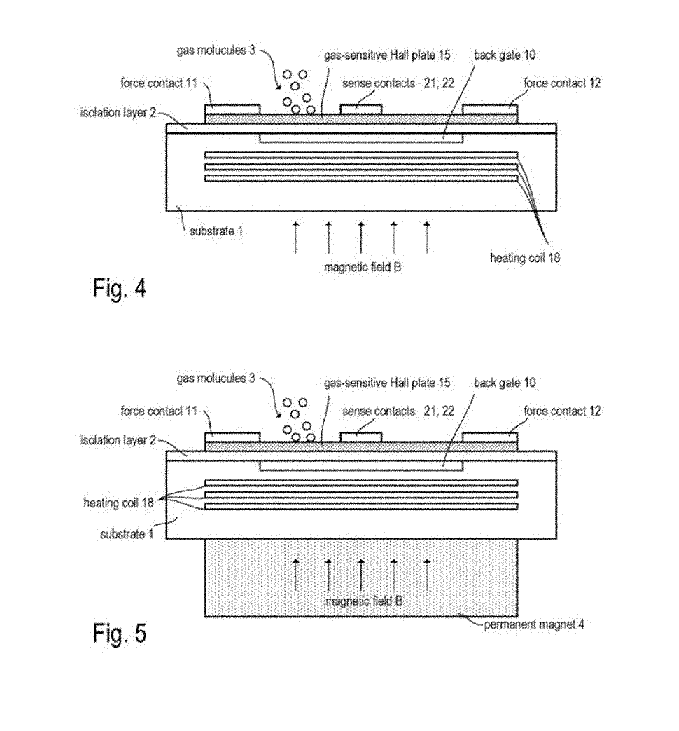

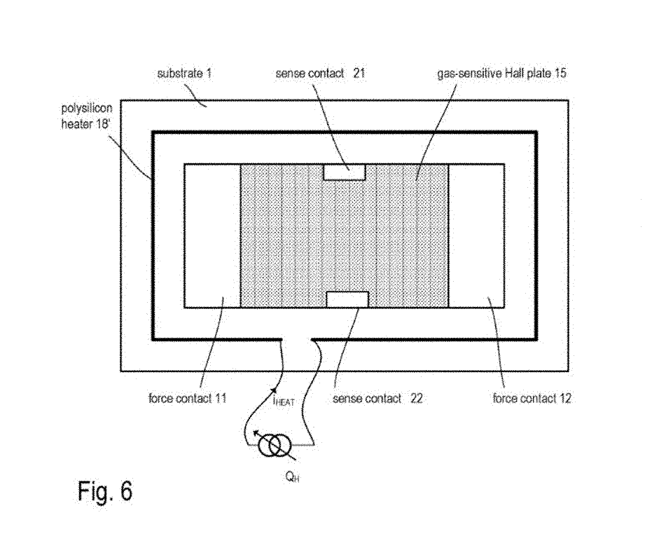

FIG. 4 illustrates a cross-sectional view of another exemplary embodiment of a gas-sensitive Hall sensor. The example of FIG. 4 is essentially identical with the previous example of FIG. 1 except that an additional coil 18 is provided in the substrate 1. The coil may be integrated in the silicon substrates using any known techniques. Similar techniques are used to produce coils for integrated coreless transformers or the like. The coil 18 may be used to generate the magnetic field B (during a measurement period) and/or to generate heat to heat up the gas-sensitive layer for desorbing gas molecules from the gas-sensitive layer 15 (during a regeneration period). For the purpose of heating, a polysilicon (polycrystalline silicon) micro-heater may be used instead of the coil 18 (see description with reference to FIG. 6). Apart from the coil 18, the components shown in FIG. 4 are identical with FIG. 1 and the respective explanation is therefore not repeated here.

FIG. 5 illustrates a cross-sectional view of another exemplary embodiment of a gas-sensitive Hall sensor. The example of FIG. 5 is essentially identical with the previous FIG. 4 but with an additional permanent magnet 4 arranged subjacent to the semiconductor substrate 1. The permanent magnet 4 is vertically magnetized to generate a vertically oriented (i.e. perpendicular to the surface of the Hall plate 15) magnetic field B, which is needed for the operation of the gas sensor. In this case the heating coil 18 is used for the heating (regeneration) of the gas-sensitive layer 15. Apart from the permanent magnet 4, the components shown in FIG. 5 are identical with FIG. 4 and the respective explanation is therefore not repeated here.

FIG. 6 is a top view illustrating essentially the same example as shown in FIG. 2 but with an additional polysilicon micro-heater arranged on the substrate 1 around the gas sensitive Hall plate 15. The micro-heater is formed by a strip line made of polysilicon. However, materials other than polysilicon (e.g. metals) may be used instead. The strip line forms a loop on the substrate 1 around the Hall plate 15. However, the strip lines may also be provided below the Hall plate 15 (below the isolation layer 2, see FIG. 1) and may also have a different geometry (e.g. a meander shape). When supplied with a current i_{HEAT} the energy R_{POLY}²·i_{HEAT} is dissipated into the substrate and the local temperature of the substrate 1 and thus the temperature of the Hall plate 15 increases. The controllable current source OH is representative for any electronic circuit that is configured to provide the current i_{HEAT} for the micro-heater. As mentioned the micro-heater may be activated periodically to “refresh” the Hall plate 15 (desorb the gas atoms/molecules from the Hall plate) in each measurement cycle. In case the back-gate region 10 (not shown in the top view, see cross section of FIG. 1) is formed by a polysilicon layer, the back-gate region may additionally be used as a micro-heater, thus avoiding the need for a separate micro-heater.

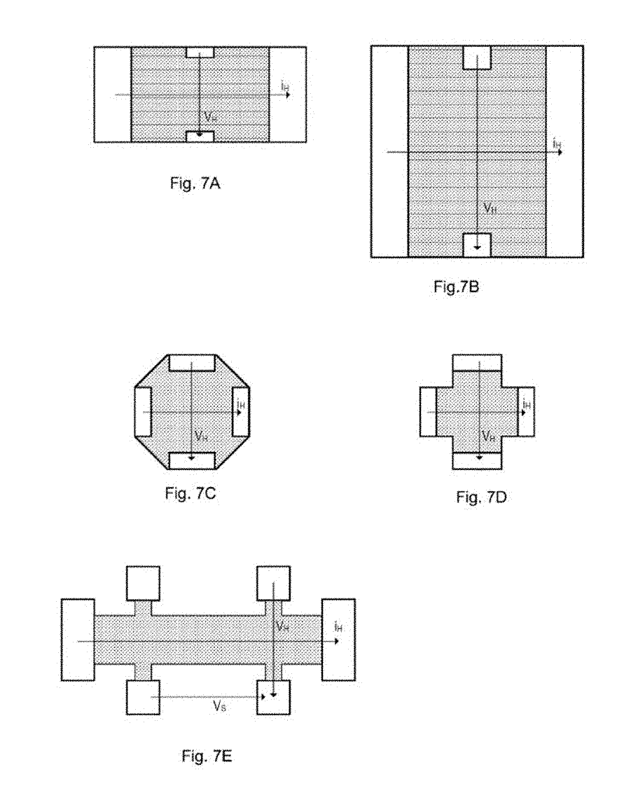

In the examples of FIGS. 1 to 6 the Hall plate 15 has the shape of a rectangular plate. However, the Hall plate 15 does not necessarily have to have a rectangular layout. FIG. 7 (7A-7D) illustrates top views of different possible layouts for the Hall plate 15. FIG. 7A shows a rectangular shape as in the previous examples. FIG. 7B illustrates a quadratic layout, FIG. 7C an octagonal layout, and FIG. 7D shows a complex polygon layout in the shape of a cross. Various further layouts are possible. The exemplary layout in FIG. 7E allows the measurement of the Hall voltage V_{H} (in a transversal direction) as well as the voltage drop V_{S} due to the ohmic resistance R_{XX} of the Hall plate 15 (see also FIG. 8, top diagram), wherein V_{S}=R_{XX}·1_{H}.

As mentioned above the charge carrier density n in the gas-sensitive layer 15 (see examples of FIGS. 1 to 5) affects the Hall constant R_{H} (see equation 2), and the charge carrier density n is affected by gas molecules 3 adsorbed at the surface of the gas-sensitive layer 15 (Hall plate). Generally, the Hall constant R_{H} increases as the charge carrier density n decreases. The charge carrier density n may also be controlled by applying a gate voltage V_{G} to the back-gate region 10 (see FIGS. 1, 4, and 5). The diagrams of FIG. 87 illustrate how the voltage V_{G} affects the (ohmic) resistance R_{XX} of the gas-sensitive layer 15 (see top diagram of FIG. 8) and the Hall constant R_{H} (see bottom diagram of FIG. 8). The solid lines in the diagrams of FIG. 8 represent a situation, in which no gas molecules 3 are present, which could be adsorbed at the gas-sensitive layer 15. The characteristic curves (solid lines) are shifted to the right or the left in the presence of gas molecules 3. In case the gas molecules are donators (e.g. NH₃) the curve is shifted to the right (dotted line), in case the gas molecules are acceptors (NO₂) the curve is shifted to the right (dashed line). In other words, the gate voltage V_{G} may be varied to “calibrate” the Hall plate. Furthermore, the back-gate allows to “switch” between electron conduction and hole conduction by applying an appropriate gate voltage V_{G}, wherein the Hall constant R_{H} is positive for hole conduction and negative in case of electron conduction. When holes and electrons are balanced (at the socalled Dirac point), then the Hall constant is zero.

FIG. 9 is a circuit diagram illustrating one exemplary circuit arrangement, which may be used to drive the gas sensor and to control the gate voltage V_{G} applied to the back gate 10 of the gas sensor. In the present example, a sensor control unit 50, which includes a gate control circuit, provides a constant sensor current i_{H} which is fed through the gas-sensitive Hall plate 15 (see FIG. 1) via the force contacts 11 and 12. Before starting actual measurements, the resulting Hall voltage V_{H} (see equation 1) may be regulated to zero by appropriately tuning the gate voltage V_{G} applied to the back gate 10 of the gas sensor (see also FIG. 1). Such a calibration V_{H}=0) allows a highly sensitive detection/measurement of gas molecules or changes of the gas molecule concentration in the ambient atmosphere. Moreover, it allows to distinguish between gas molecules, which act as donators (e.g. NH₃) or acceptors (e.g., NO₂). Therefore, the sensor can also be used in liquids to distinguish OH⁻ (hydroxide) and H₃O⁺ (oxonium) ions, i.e. for the measurement of pH value. In this context it should be noted that, dependent on the material used for the Hall plate 12, the embodiments described herein may also be used within a liquid atmosphere instead of a gaseous atmosphere. The term “chemically sensitive” is used as a collective term for both, “gas-sensitive” and “sensitive to liquids”.

In one exemplary embodiment, the Hall voltage VH is continuously regulated to zero (for a constant magnetic field B). In this case the gas sensor is continuously operated in the Dirac point, and the gate voltage V_{G}, which is necessary to make the Hall voltage V_{H} zero, may be used as sensor signal which is indicative for the presence of gas molecules.

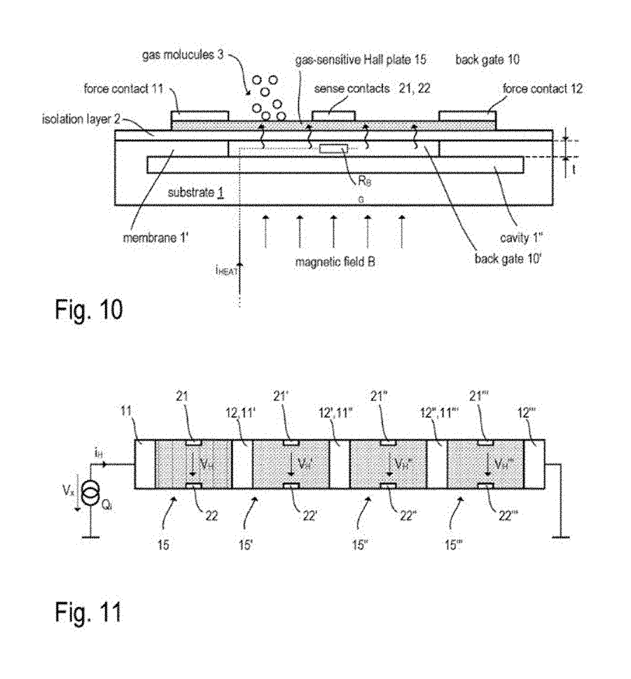

As mentioned above with reference to FIG. 4, a micro-heater may be provided to heat up the gas-sensitive Hall plate 15 in order to resorb the gas molecules previously adsorbed at the surface of the gas-sensitive Hall plate 15. While in the previous example of FIG. 4 a heating coil is used to heat up the substrate and thus the Hall plate 15, an electrical current/HEAT is fed through the back-gate region 10 instead. The electrical resistance of the back-gate region 10 (symbolized in FIG. 10 by the resistor R_{BG}) causes a dissipated power of i_{HEAT}²·R_{BG}, which heats up the back-gate region 10 and thus also the superjacent gas-sensitive Hall plate 15. In order to achieve the desired increase in temperature, the heat capacity of the heated material should be small. This is the case when the mass of the heated material is small; and this can be achieved by forming the gas-sensitive layer 15 on a membrane 1′ as shown in the example of FIG. 10. The cavity 1″ in the substrate 1 below the membrane 1′ is an effective heat insulation and thus most of the heat generated by the current i_{HEAT} in the back gate region 10 is dissipated through the Hall plate 15.

For repeated measurements, the gas-sensitive layer 15 may cyclically be regenerated by heating (see FIGS. 4, 5, and 10). After regeneration of the gas-sensitive layer 15, a calibration (i.e. tuning of the gate voltage V_{G}) may subsequently be performed as explained with reference to FIG. 9.

FIG. 11 illustrates an array of Hall plates 15, 15′, 15″, 15′″, which are connected in series such that they carry the same sensor current i_{H} provided by the current source Qᵢ (see FIG. 3). In the present case the array is composed of four Hall plates 15. However, in different embodiments only two Hall plates may be provided (e.g. for differential measurements). Other embodiments may include three or more Hall plates. Due to the series connection the force contact 12 of the first Hall plate 15 and the force contact 11′ of the second Hall plate 15′ may formed as one piece. The sensitivity to gas atoms or molecules may be different for the different Hall plates 15, 15′, 15″ and 15″. In this case the Hall voltages V_{H}, V_{H}′, V_{H}″ and V_{H}′″, which may be tapped at the Hall plates 15, 15′, 15″ and 15′″, respectively, are different and may be indicative for the gas or specific gas components interacting with the Hall plates. The array of Hall plates 15, 15′, 15″ and 15′″ may be formed on one single semiconductor chip. Alternatively, separate chips may be used for the different hall plates, which may be, however, included in the same chip package. In case of differential measurements an array of two Hall plates 15 and 15′ may be used, wherein on Hall plate is passivated so that it cannot interact with gas molecules in the environment. Both Hall plates 15 and 15′ “see” the same sensor current i_{H} and the same magnetic field B, but only one Hall plate is subjected to the gas. In this case the difference V_{H}-V_{H}′ of the Hall voltages V_{H} and V_{H}′ of the two hall plates may be evaluated to detect the gas atoms/molecules and/or to measure their concentration in the surrounding atmosphere.

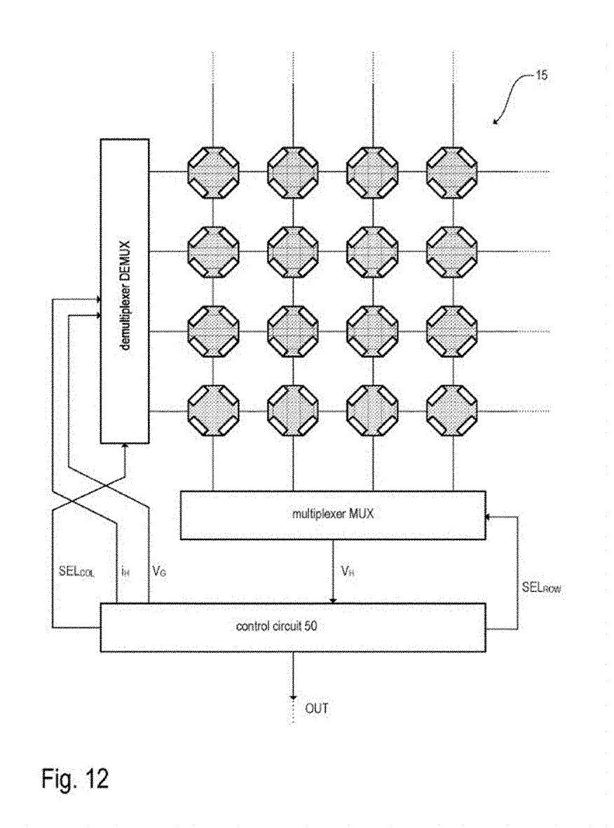

FIG. 12 schematically illustrates another example of an array of Hall elements which may be controlled using multiplexer/demultiplexer circuits to select one or more specific Hall elements of the array. By appropriate control of the multiplexer MUX and demultiplexer DEMUX one or more individual Hall plates 15 of the array may be chosen and used for a specific measurement. The Hall plates 15 may be arranged matrix-like and distributed along rows and columns as shown in FIG. 12. However, alternative arrangements are possible. The control unit 50 may perform a similar function as the control circuit 50 shown in FIG. 9. That is, the control unit 50 provides a sensor current i_{H} to a selected Hall element 15, receives the Hall voltage V_{H} tapped at the selected Hall element 15, and applies a gate voltage V_{G} to the selected Hall element 15. Dependent on the actual implementation, the gate voltage V_{G} may be regulated such that the Hall Voltage V_{H} remains at a set-point of zero volts. However, different regulation schemes may be used. A Hall element may be selected by the select signals SELROW and SELCOL supplied to the multiplexer MUX and the demultiplexer DEMUX, respectively. The multiplexer MUX is configured to direct a signal (e.g. the gate voltage V_{G} and/or the sensor current i_{H} or signals representing V_{G} or i_{H}, a signal for activating the micro-heater, etc.) to a Hall element identified by the select signal S_{ROW}. The demultiplexer DEMUX is configured to direct a signal (e.g. the Hall voltage V_{H} or a signal representing V_{H}) tapped at a Hall element identified by the select signal S_{COL} to the control circuit 50.

In the present example as described above, a specific Hall element may be selected and then used for the detection of gas atoms/molecules and/or for measurement of concentration of gas atoms/molecules in the surrounding atmosphere. Each Hall element may be differently chemically functionalized to be sensitive for different gas atoms/molecules. By making a sequence of measurements and sequentially selecting different Hall elements, different types of gases may be identified. Moreover, more than one Hall elements may be selected at one time. In that case, two or more Hall elements may be connected in parallel to increase sensitivity (as the total chemically active area of the gas sensitive layers 15 increases). In this context “connected in parallel” means that the sensor outputs (where the Hall voltage VH is tapped) are connected in parallel. With regard to the sensor current i_{H} the Hall elements 15 are connected in series so that every Hall element 15 carries the same sensor current i_{H}.

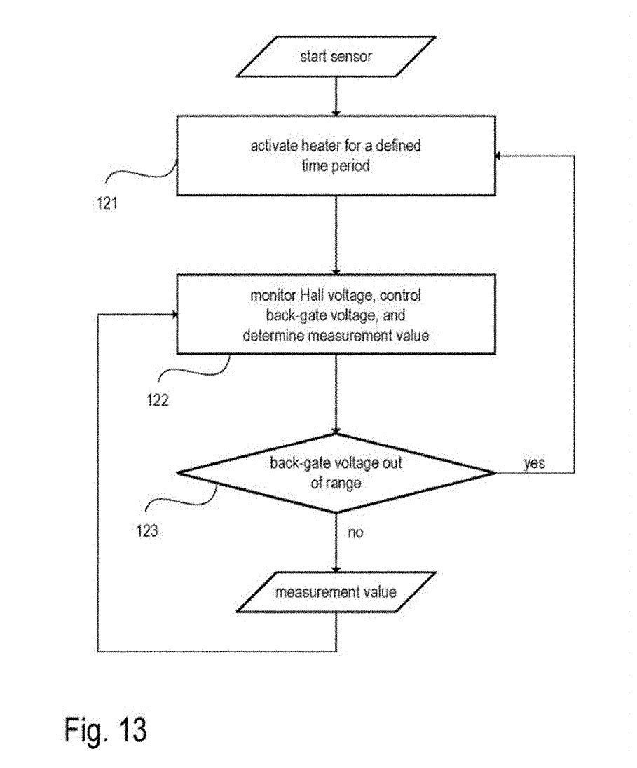

FIG. 13 illustrates a flow chart illustrating a method of operating the gas sensors described herein. The method may be implemented, for example, by using an appropriately configured control unit such as the sensor control unit 50 in the example of FIG. 9. At the beginning of measurements, the gas sensitive hall plate is “refreshed” by heating up the sensor. The heating results in a desorption of gas molecules/atoms that have previously been adsorbed at the surface of the gas-sensitive Hall plate (see FIG. 5). For this purpose the micro-heater included in the sensor may be activated for a defined time period (and deactivated after that time period, see FIG. 13, step 121). During operation of the sensor, the Hall voltage is continuously monitored (see FIG. 9) and the gate voltage V_{G}, which is applied to the back gate region 10 of the sensor (see, e.g., FIG. 5), is controlled such that the sensor is operated in a defined operating point (cf. the explanations with reference to FIGS. 8 and 9). The Hall voltage can be processed (e.g. digitized) to obtain a measurement value in the desired form (see FIG. 13, step 122). However, the desired information is already in the Hall voltage V_{H} and/or the back-gate voltage V_{G}. Due to the adjustment of the gate voltage V_{G} (to maintain the operating point of the sensor) a continuous heating of the sensor is not needed. Only if the gate voltage V_{G} leaves a pre-defined target range, the heater may be again activated to refresh the Hall plate, and the measurement cycle starts over. The check, whether the gate voltage V_{G} is still within the desired target range is labelled as step 123 in the example of FIG. 13. As an alternative, the refreshing of the gas-sensitive Hall-plate may be time-triggered. In this case, the Hall plate is refreshed when a pre-defined cycle time has elapsed. When using two sensors, these could be operated in an alternating manner so that one sensor is refreshing (heater active) while the other sensor is in measuring mode (see FIG. 13, step 122).

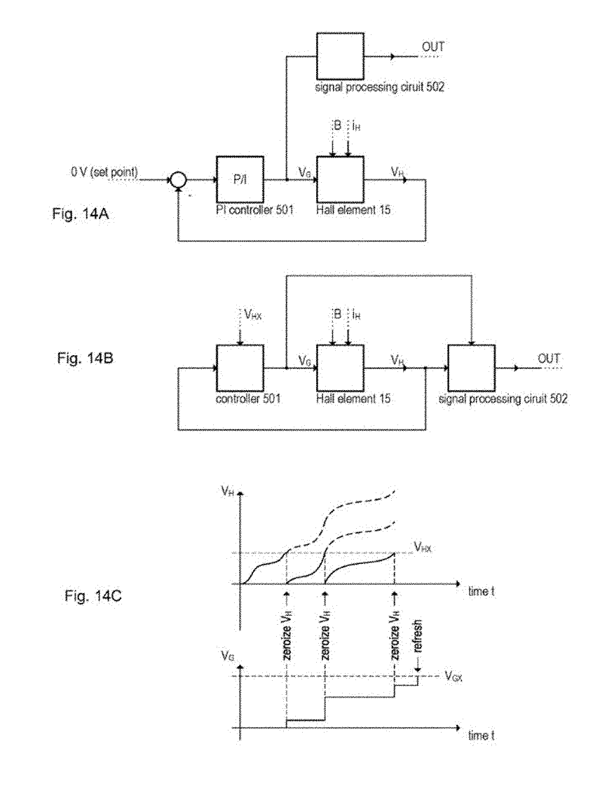

FIG. 14 illustrates by means of block and timing diagrams two exemplary regulation schemes for regulating the gate voltage applied to the back-gate of a Hall element. FIG. 14a illustrates a control loop, which may be used to continuously regulate the gate voltage V_{G} for a specific Hall element 15 such that the Hall voltage V_{H} tapped at the Hall element 15 is kept at a level of substantially zero volts. That is, the set-point for the control loop is zero. In this case the Hall element 15 is continuously operated in the most-sensitive operation point, i.e. the zero-crossing of the curve in the bottom diagram of FIG. 8. In this regard, reference is made to FIGS. 8 and 9 the respective description. As the Hall voltage V_{H} is substantially zero in this example, in information about the concentration of gas atoms/molecules (or information about whether gas atoms/molecules have been detected) is solely in the gate voltage V_{G} applied to the back gate 10 of the Hall element 15. If the gate voltage V_{G} exceeds a pre-defined value, a refresh of the Hall element 15 may be triggered, e.g., by activation of the micro-heater. In the present examine a proportional/integral (PI) controller 501 is used to adjust the gate voltage V_{G} in order to maintain the Hall voltage V_{H} at zero level. However, other controller types may be used.

FIG. 14b illustrates another example of a control loop for adjusting the gate voltage V_{G}. Different from the previous example, the Hall voltage V_{H} is not continuously regulated to zero but rather zeroized either in regular time intervals or when the Hall voltage V_{H} exceeds a pre-defined threshold level V_{HX}. However, more complex schemes for zeroizing the Hall voltage may be used. In the present example, the Hall voltage V_{H} is zeroized (by appropriate adjustment of the gate voltage V_{G}) each time when the Hall voltage reaches or exceeds the threshold level V_{HX}. This function is further illustrated by the timing diagram of FIG. 14c. Each time the Hall voltage V_{H} reaches the threshold V_{HX}, the gate voltage V_{G} is adjusted to set the Hall voltage V_{H} to zero. Then the gate voltage is constant until the Hall voltage V_{H} again reaches the threshold V_{HX}. When the gate voltage V_{G} leaves a predefined range (e.g. from ^{˜}V_{GX} to V_{GX}), the measurement may be paused and the Hall element may be refreshed, e.g. by activation of the micro-heater (see FIGS. 4-6).

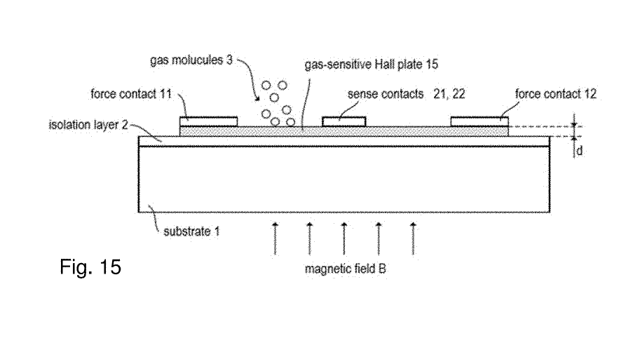

FIG. 15 is a cross-sectional view of a fifth exemplary embodiment of a gas-sensitive Hall device. This Hall device is essentially identical with the example shown in FIG. 1, except that this Hall device does not include a back gate 10. While this Hall device and others are described as being gas sensitive, it is understood that the devices are more generally chemically sensitive.

Without the back gate 10, a specific gas molecule concentration is not detected. The gas-sensitive Hall plate 15 without the back gate 10 is rather sensitive to a gas molecule type and more simply detects a presence of a gas molecule type, for example, carbon monoxide, carbon dioxide, etc but not a specific gas concentration of such gas molecule type. If a presence of the gas molecule type is detected, a safety measure can be taken, such as switching off an electrical device.

The components shown in FIG. 15 are substantially identical with those of FIG. 1, with the exception of the back gate 10, and thus respective explanations are therefore not repeated here.

An array of gas-sensitive Hall plates 15 of FIG. 15 may be formed. The gas-sensitive Hall plates 15 are connected in series and chemically functionalized differently to provide sensitivity to different atoms or molecules. This array may be used to monitor a multi-phase gas composition or a multi-gas composition. Such arrays are described in detail above, and for the sake of brevity, further explanation is not repeated here.

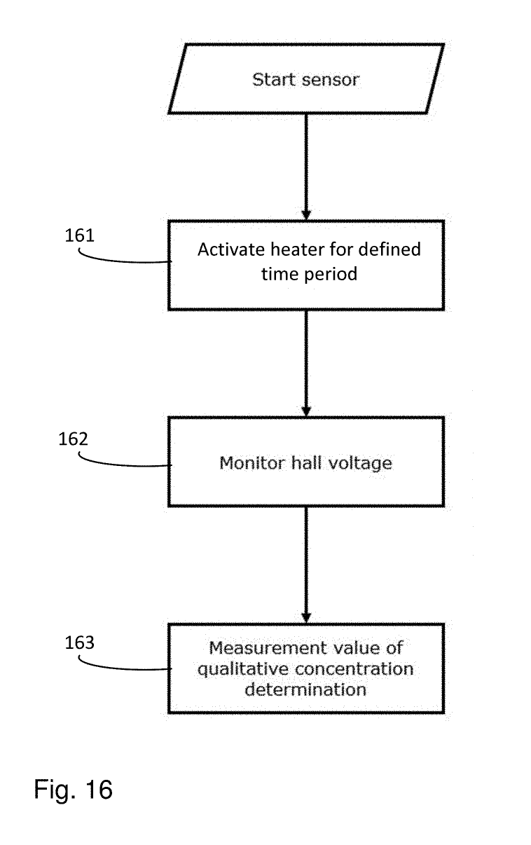

FIG. 16 illustrates a flow chart of a method of operating the gas-sensitive Hall device of FIG. 15.

The method may be implemented, for example, using an appropriately configured control unit as described with respect to FIG. 9 above. At the beginning of measurements, the gas sensitive-hall plate 15 is “refreshed” by heating up the sensor. The heating results in a desorption of gas molecules/atoms that have been adsorbed before the heating at the surface of the gas-sensitive Hall plate 15, as described above. For this purpose a micro-heater included in the sensor may be activated for a defined time period, and deactivated after that time period (step 161) in order to achieve an intended amount of heating of the gas sensitive hall plate 15. During operation of the sensor, the Hall voltage is continuously monitored (step 162). The Hall voltage can be processed (e.g., digitized) to obtain a measurement of a qualitative concentration of a gas (step 163). As mentioned above, although this method is described as measuring a gas, this disclosure is more broadly intended to measure a chemical.

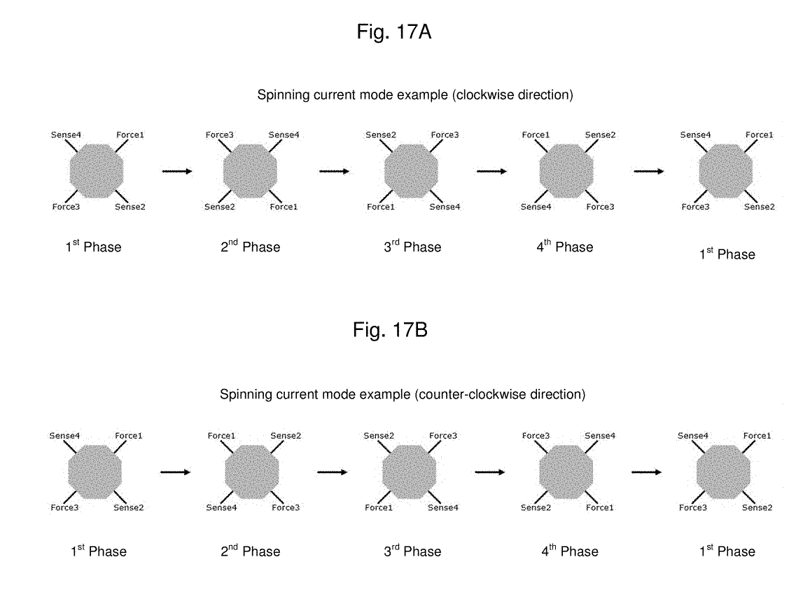

FIGS. 17A-17B illustrate spinning current mode examples of the gas-sensitive Hall device of FIG. 15.

A spinning current method results in a more precise measurement by averaging out contributions of imperfections of the gas-sensitive Hall plate 15 in order to reduce an offset. The force and sense electrodes are not fixed, but are instead rotated. More specifically, in a spinning current mode, electrodes feed sensor current through the gas-sensitive Hall plate 15 in a first sequence of directions, and tap the Hall voltage at the gas-sensitive Hall plate 15 in a second sequence of directions. The second sequence of directions may be perpendicular to the first sequence of directions. More specifically, the measurement direction is rotated according to predefined steps during a cycle, for example, 90°, at a particular clock frequency. The sensor current flows from one electrode to a facing electrode, the Hall voltage being tapped off at the transverse electrodes, whereupon the measurement direction is rotated through 90° at the next cycle, that is, the next measurement phase. The Hall voltages measured in the individual measurement phases are evaluated by a suitable correctly signed and weighted summation or subtraction. The offset voltages during a revolution should roughly cancel one another out, so that the parts of the Hall signal which depend on the magnetic field are retained. In other words, by averaging over the current spinning phases offset errors are reduced, while a signal to noise ratio is increased.

FIG. 17A illustrates a spinning current mode example having four measurement phases rotating in a clockwise direction. In the first phase, the first diagonal has Force1 electrode and Force3 electrode, with Force1 electrode in the upper right corner and Force3 electrode in the lower left corner. In the other diagonal are Sense4 electrode and Sense2 electrode, with Sense4 electrode in the upper left corner and Sense2 electrode in the lower right corner. In the second phase each of these electrodes has spun clockwise by 90 degrees, in the third phase by another 90 degrees, and in the fourth phase by another 90 degrees. The phase after the fourth phase is identical to the first phase. In this example there are four different phases, but there may be any number of phases as suitable. Also, there may be any number of rotations as sufficient to obtain an average of the measurement values to reduce measurement offset increase measurement signal-to-noise ration and hence accuracy of measurements.

FIG. 17B illustrates a spinning current mode example having four measurement phases that is similar to the example of FIG. 17A, except that the rotation is in the counter-clockwise direction.

While various embodiments of the invention have been described, it will be apparent to those of ordinary skill in the art that many more embodiments and implementations are possible within the scope of the invention. Accordingly, the invention is not to be restricted except in light of the attached claims and their equivalents. With regard to the various functions performed by the components or structures described above (assemblies, devices, circuits, systems, etc.), the terms (including a reference to a “means”) used to describe such components are intended to correspond, unless otherwise indicated, to any component or structure that performs the specified function of the described component (i.e., that is functionally equivalent), even if not structurally equivalent to the disclosed structure that performs the function in the exemplary implementations of the invention illustrated herein.

What is claimed is:

1. A chemically sensitive Hall device, comprising:
a substrate;
a chemically sensitive layer arranged on the substrate and configured to operably interact with atoms or molecules of a gaseous or liquid fluid;
first electrodes connected to the chemically sensitive layer and configured to feed a sensor current through the chemically sensitive layer; and
second electrodes connected to the chemically sensitive layer and configured to tap a Hall voltage at the chemically sensitive layer.

2. The chemically sensitive Hall device according to claim 1, further comprising:
a back gate arranged on or integrated in the substrate, and isolated from the chemically sensitive layer by an isolation layer.

3. The chemically sensitive Hall device according to claim 1, wherein the Hall device is a spinning current Hall device.

4. The chemically sensitive Hall device according to claim 3, wherein the spinning current Hall device is configured to cause the first and second electrodes to feed the sensor current through the chemically sensitive layer in a first sequence of directions, and to tap the Hall voltage at the chemically sensitive layer in a second sequence of directions.

5. A sensor array comprising at least two chemically sensitive Hall devices in accordance with claim 1, wherein the at least two chemically sensitive Hall devices are integrated in one substrate or in one sensor package.

6. The sensor array of claim 5, wherein at least two of the Hall devices have chemically sensitive layers which are chemically functionalized differently to provide sensitivity to different atoms or molecules.

7. The sensor array of claim 6, further comprising:
a control circuit coupled to the first electrodes of the chemically sensitive Hall devices and the second electrodes of the chemically sensitive Hall devices, and configured to select the at least two Hall elements sequentially.

8. The sensor array of claim 6, further comprising:
a control circuit coupled to the first electrodes of the chemically sensitive Hall devices and the second electrodes of the chemically sensitive Hall devices, and configured to select two or more Hall devices, and the selected Hall devices are connected in parallel.

9. The chemically sensitive Hall device according to claim 1, wherein a coil is integrated in the substrate subjacent to the chemically sensitive layer.

10. The chemically sensitive Hall device according to claim 9, wherein the coil is operably supplied with current to generate a magnetic field having a field component perpendicular to a top surface of the chemically sensitive layer.

11. The chemically sensitive Hall device according to claim 10, wherein the coil is configured to be operated as a heating coil to generate heat for the heating the chemically sensitive layer.

12. The chemically sensitive Hall device according to claim 1, further comprising:
a permanent magnet configured to generate a magnetic field having a field component perpendicular to a top surface of the chemically sensitive layer.

13. The chemically sensitive Hall device according to claim 1, further comprising:
a heating circuit having a heat generating element configured to heat up the chemically sensitive layer to desorb atoms or molecules from the chemically sensitive layer.

14. The chemically sensitive Hall device according to claim 13, wherein the chemically sensitive layer is used as a heat generating element, and the sensor current is increased to heat up the chemically sensitive layer.

15. The chemically sensitive Hall device according to claim 13, wherein the heating circuit is configured to cyclically heat up the gas-sensitive layer.

16. The chemically sensitive Hall device according to claim 1, wherein the chemically sensitive layer comprises a Hall element.

17. A method for operating a sensor which includes a chemically sensitive Hall element arranged on a substrate, the method comprising:
applying a sensor current to the chemically sensitive Hall element so that the sensor current passes through the Hall element in a first direction;
sensing a Hall voltage at the Hall element along a second direction; and
monitoring the Hall voltage to obtain a qualitative concentration measurement of a chemical.

18. The method according to claim 17, wherein the Hall element is a spinning current Hall element, and the applying and the sensing are performed in accordance with a spinning current mode.

19. The method according to claim 17, wherein:
the Hall element is a spinning current Hall element,
the applying comprises applying the sensor current to the chemically sensitive Hall element so that the sensor current passes through the Hall element in a first sequence of directions, and
the sensing comprises sensing the Hall voltage at the Hall element along a second sequence of directions.

20. The method according to claim 17, further comprising:
heating the chemically sensitive Hall element to desorb atoms or molecules from the chemically sensitive Hall element.
